(19) United States
(12) Patent Application Publication
(10) Pub. No.: US 2025/0380496 A1
(43) Pub. Date: Dec. 11, 2025

(54) SEMICONDUCTOR DEVICE

(71) Applicant: Samsung Electronics Co., Ltd., Suwon-si (KR)

(72) Inventors: Jeewoong Kim, Suwon-si (KR); Dongyun Lee, Suwon-si (KR); Seungmin Cha, Suwon-si (KR); Minchan Gwak, Suwon-si (KR); Jinkyu Kim, Suwon-si (KR); Yunsuk Nam, Suwon-si (KR)

(21) Appl. No.: 19/078,481

(22) Filed: Mar. 13, 2025

(30) Foreign Application Priority Data
Jun. 5, 2024 (KR) 10-2024-0073873

(51) Int. Cl. H10D 84/83; H10D 30/00; H10D 30/01; H10D 62/10; H10D 62/13; H10D 64/23; H10D 84/01

(52) U.S. Cl. CPC H10D 84/8312; H10D 30/503; H10D 30/506; H10D 62/115; H10D 62/121; H10D 62/151; H10D 64/256; H10D 30/019; H10D 84/0149; H10D 84/0151

(57) ABSTRACT

A semiconductor device includes insulating isolation patterns each including a void, semiconductor patterns respectively stacked on the insulating isolation patterns, gate structures respectively extending around the semiconductor patterns, first and second source/drain patterns respectively connected to opposing sides of the plurality of semiconductor patterns in a first direction, an active contact structure extending between insulating isolation patterns adjacent to the first source/drain pattern and connected to the first source/drain pattern, a dummy contact structure extending between the insulating isolation patterns adjacent to the second source/drain pattern and electrically isolated from the second source/drain pattern, and an interconnection line on lower surfaces of the insulating isolation patterns, electrically connected to the active contact structure, and electrically isolated from the dummy contact structure.

### CROSS-REFERENCE TO RELATED APPLICATION(S)

This application claims the benefit of priority under 35 USC § 119(a) of Korean Patent Application No. 10-2024-0073873 filed on Jun. 5, 2024 in the Korean Intellectual Property Office, the entire disclosure of which is incorporated herein by reference for all purposes.

### BACKGROUND

The present inventive concept relates generally to semiconductor devices, and more particularly to semiconductor devices having improved electrical characteristics and reliability.

As demands for high performance, speed, and/or multifunctionality in semiconductor devices increase, the degree of integration of semiconductor devices is increasing. In accordance with the trend toward higher integration of semiconductor devices, semiconductor devices having a BackSide Power Delivery Network (BSPDN) structure in which a power rail is placed on the back of a wafer are being developed. Additionally, to reduce limitations in operating characteristics due to size reduction of planar MOSFETs (metal oxide semiconductor field-effect transistors), efforts are being made to develop a semiconductor device having a three-dimensional channel.

### SUMMARY

Example embodiments provide a semiconductor device having improved electrical characteristics and reliability.

According to example embodiments, a semiconductor device includes a plurality of insulating isolation patterns spaced apart from each other in a first direction and each extending in a second direction intersecting the first direction, each of the plurality of insulating isolation patterns including a void; a plurality of channel structures respectively disposed on the plurality of insulating isolation patterns and having a plurality of semiconductor patterns stacked and spaced apart from each other in a vertical direction intersecting the first and second directions; a plurality of gate structures respectively intersecting the plurality of channel structures in the second direction and surrounding (i.e., extending around) the plurality of semiconductor patterns; a first source/drain pattern and a second source/drain pattern provided between the plurality of channel structures and respectively connected to both sides of the plurality of semiconductor patterns in the first direction; an active contact structure extending between insulating isolation patterns adjacent to the first source/drain pattern among the plurality of insulating isolation patterns, and electrically connected to the first source/drain pattern; a dummy contact structure extending between insulating isolation patterns adjacent to the second source/drain pattern among the plurality of insulating isolation patterns, and electrically isolated from the second source/drain pattern; and an interconnection line on lower surfaces of the plurality of insulating isolation patterns, connected to the active contact structure, and electrically isolated from the dummy contact structure.

According to example embodiments, a semiconductor device includes a plurality of insulating isolation patterns spaced apart from each other in a first direction and each extending in a second direction intersecting the first direction, each of the plurality of insulating isolation patterns including a void; a plurality of channel structures respectively disposed on the plurality of insulating isolation patterns and each having a plurality of semiconductor patterns stacked and spaced apart from each other in a vertical direction intersecting the first and second directions; a plurality of gate structures respectively intersecting the plurality of channel structures in the second direction and surrounding the plurality of semiconductor patterns; a first source/drain pattern and a second source/drain pattern between the plurality of channel structures and respectively connected to both sides of the plurality of semiconductor patterns in the first direction; an active contact structure extending in the vertical direction between insulating isolation patterns adjacent to the first source/drain pattern among the plurality of insulating isolation patterns, and electrically connected to the first source/drain pattern; a dummy contact structure extending in the vertical direction between insulating isolation patterns adjacent to the second source/drain pattern among the plurality of insulating isolation patterns and electrically isolated from the second source/drain pattern; an upper contact structure extending in the vertical direction between the plurality of gate structures and electrically connected to the second source/drain pattern; an interconnection insulating layer on lower surfaces of the plurality of insulating isolation patterns and having portions extending into the void; and an interconnection line on a lower surface of the interconnection insulating layer and having an interconnection via electrically connected to the active contact structure penetrating (i.e., extending in) the interconnection insulating layer.

According to example embodiments, a semiconductor device includes a base structure having an insulating isolation pattern extending in a first direction, the insulating isolation pattern having a void therein; a plurality of semiconductor patterns stacked on the insulating isolation pattern and spaced apart from each other in a direction perpendicular to an upper surface of the base structure; a gate structure surrounding the plurality of semiconductor patterns in a second direction crossing the first direction; a first source/drain pattern and a second source/drain pattern on both sides of the gate structure and connected to the plurality of semiconductor patterns; an active contact structure extending in the vertical direction from a lower surface of the base structure, extending in the base structure and electrically connected to the first source/drain pattern; a dummy contact structure extending in the vertical direction from the lower surface of the base structure, with the active pattern structure and the insulating isolation pattern therebetween; and an interconnection line on lower surfaces of the active contact structure, the dummy contact structure, and the insulating isolation pattern, electrically connected to the active contact structure, and electrically separated from the dummy contact structure.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a schematic top plan view illustrating a semiconductor device according to an example embodiment;

FIG. 2 is a schematic cross-sectional view of the semiconductor device of FIG. 1 taken along line I-I′;

FIGS. 3A and 3B are schematic cross-sectional views of the semiconductor device of FIG. 1 taken along lines II1-II1′ and II2-II2′, respectively;

FIG. 4 is a schematic bottom plan view illustrating a lower contact structure of the semiconductor device of FIG. 1;

FIGS. 5 to 8 are schematic cross-sectional views illustrating semiconductor devices according to various example embodiments, respectively;

FIGS. 9A to 9J are schematic cross-sectional views depicting respective intermediate processes in a method of manufacturing a semiconductor device according to an example embodiment; and

FIGS. 10A to 10F are schematic bottom plan views of FIGS. 9D to 9I, respectively.

### DETAILED DESCRIPTION

Hereinafter, example embodiments will be described with reference to the accompanying drawings.

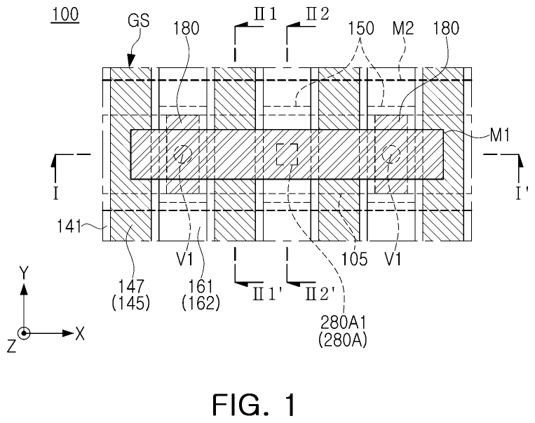

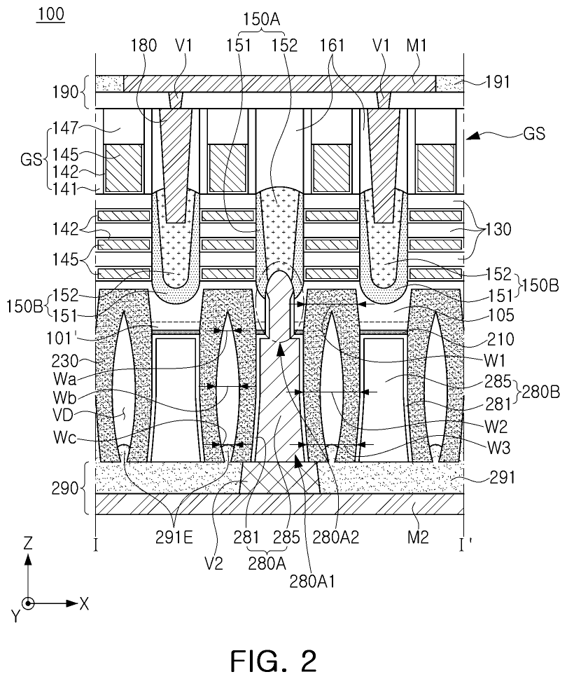

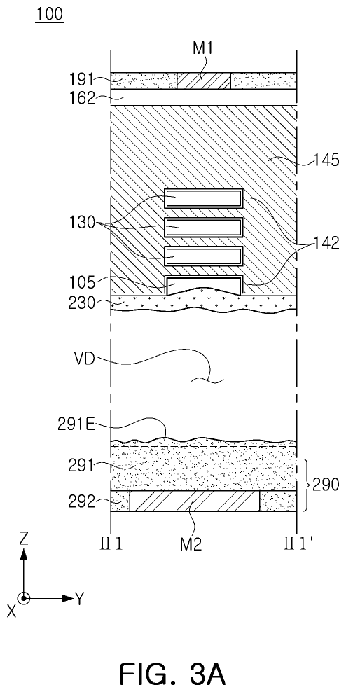

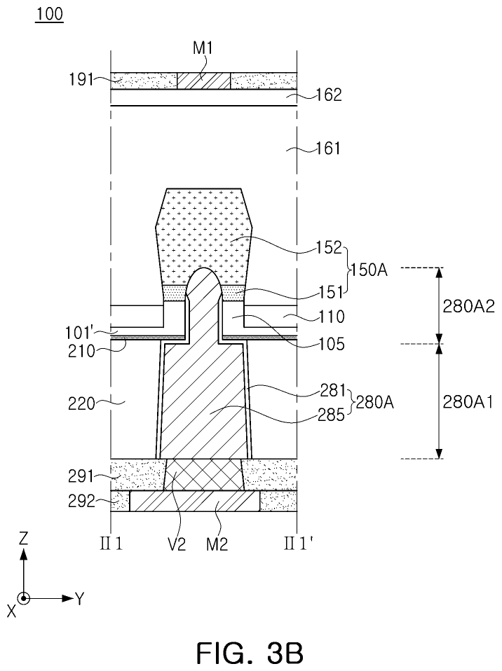

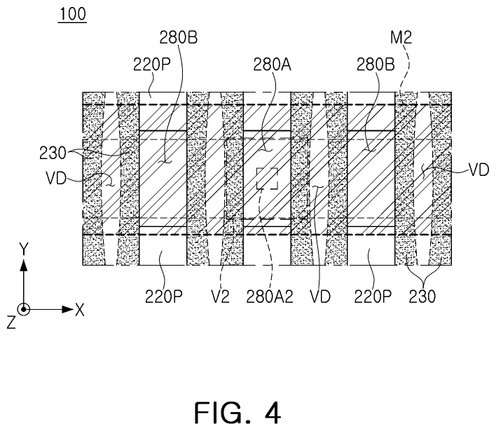

FIG. 1 is a schematic top plan view illustrating a semiconductor device according to an example embodiment, FIG. 2 is a schematic cross-sectional view of the semiconductor device of FIG. 1 taken along line I-I′, FIGS. 3A and 3B are schematic cross-sectional views of the semiconductor device of FIG. 1 taken along lines II1-II1′ and II2-II2′, respectively, and FIG. 4 is a schematic bottom plan view illustrating a lower contact structure of the semiconductor device of FIG. 1.

Referring to FIGS. 1, 2, 3A, 3B, and 4, a semiconductor device 100 according to an example embodiment includes a plurality of insulating isolation patterns 230, a plurality of semiconductor patterns 130 stacked spaced apart in a vertical direction (for example, Z-direction) on one region of the plurality of insulating isolation patterns 230, first and second source/drain patterns 150A and 150B (collectively 150) respectively connected to both (i.e., opposing) sides of the plurality of semiconductor patterns 130 in a first direction (for example, X-direction) parallel to an upper surface of a first interconnection structure 190, and a gate structure GS extending in a second direction (for example, Y-direction) parallel to the upper surface of the first interconnection structure 190 and intersecting the first direction (for example, X-direction) and surrounding the plurality of semiconductor patterns 130. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

The semiconductor device 100 according to this embodiment may include, as a base structure, a semiconductor layer 101′ disposed along lower surfaces of the gate structures GS and the first and second source/drain patterns 150A and 150B. In this embodiment, the semiconductor layer 101′ may have an active pattern 105 extending in the first direction (for example, X-direction).

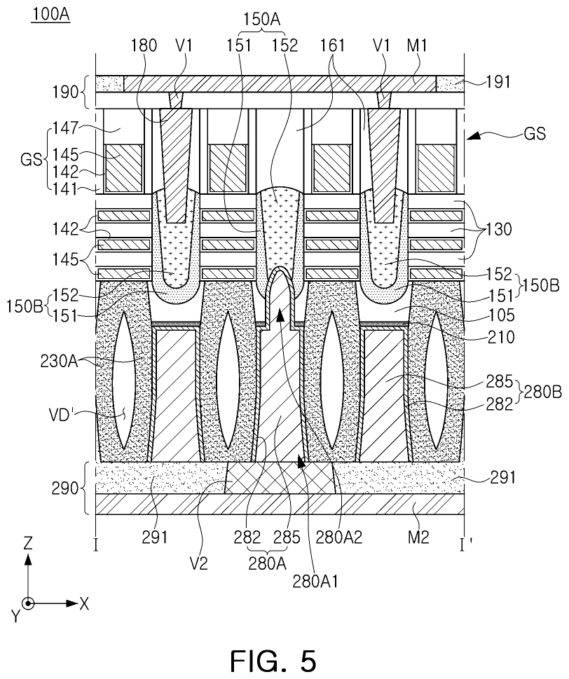

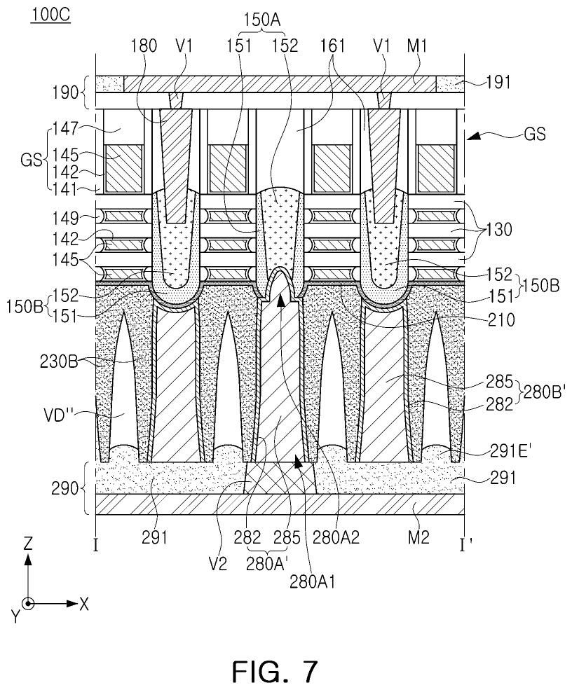

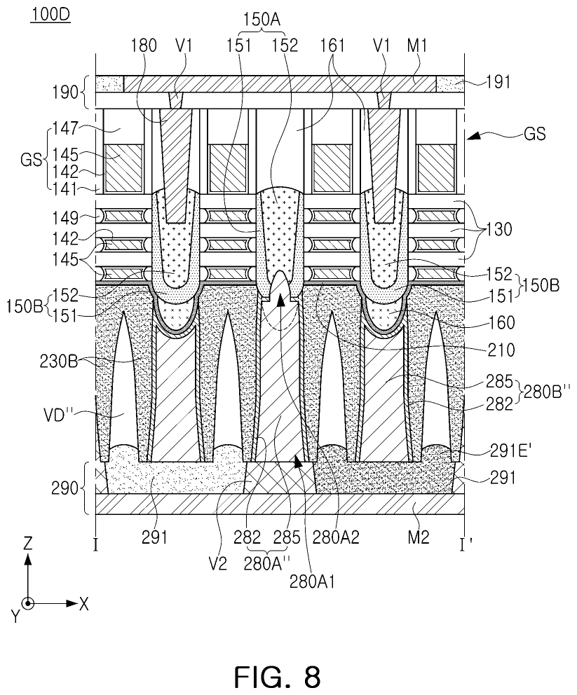

As illustrated in FIGS. 2 and 3A, a plurality of semiconductor patterns 130 are disposed on the upper surface of the active pattern 105, and the first and second source/drain patterns 150A and 150B may be disposed in a recessed area on the upper surface of the active pattern 105. The semiconductor layer 101′ introduced in this embodiment may be understood as a part of the semiconductor substrate (101 in FIG. 3B) used to form the semiconductor device 100. In some embodiments, the entire semiconductor layer 101′ may be removed so that only the active pattern 105 remains (for example, see FIG. 5), or even the active pattern 105 may be removed (for example, FIGS. 7 and 8).

In this embodiment, the plurality of semiconductor patterns 130 are provided as a channel structure of a transistor and may include, for example, at least one of silicon (Si), silicon germanium (SiGe), or germanium (Ge). In some embodiments, the plurality of semiconductor patterns 130 may be a silicon semiconductor. In this embodiment, the plurality of semiconductor patterns 130 is illustrated as three, but the number and shape may vary.

As illustrated in FIGS. 2 and 3A, the gate structure GS may include a gate electrode 145 extending in the second direction (for example, Y-direction) and surrounding the plurality of semiconductor patterns 130, a gate insulating film 142 disposed between the gate electrode 145 and the plurality of semiconductor patterns 130, gate spacers 141 disposed on both (i.e., opposing) sides of the gate electrode 145 located on the uppermost semiconductor pattern, and a gate capping layer 147 disposed on the gate electrode 145 between the gate spacers 141.

The gate electrode 145 may include a conductive material. For example, the gate electrode 145 may include at least one of W, Ti, Ta, Mo, TiN, TaN, WN, TiON, TiAlC, TiAlN, or TaAlC. In some embodiments, the gate electrode 145 may include a semiconductor material such as doped polysilicon. At least one of the gate electrodes 145 may include a multilayer structure made of different materials.

The gate insulating layer 142 may include a dielectric material. For example, the gate insulating layer 142 may include oxide, nitride, or a high-K (i.e., high dielectric constant) material. The high-K material refers to a dielectric material having a higher dielectric constant than a silicon oxide film (SiO₂), and the high-K material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In some embodiments, the gate insulating layer 142 may include two or more different dielectric layers.

Gate spacers 141 may include an insulating material. For example, the gate spacers 141 may include at least one of silicon oxide, silicon nitride, and silicon oxynitride. In some embodiments, the gate spacers 141 may include a multilayer structure made of different materials. The gate capping layer 147 may include, for example, silicon nitride, silicon oxynitride, silicon carbonitride, or silicon oxycarbonitride.

Referring to FIG. 2, the semiconductor device 100 according to this embodiment may include first and second source/drain patterns 150A and 150B respectively connected to both sides of the plurality of semiconductor patterns 140, which are channel regions, on both sides of the gate structures GS. In this embodiment, a portion of the active pattern 105 is exposed from the upper surface of the device isolation layer 110, and the first and second source/drain patterns 150A and 150B may be disposed in an exposed (for example, recessed) area of the active pattern 105 (see FIG. 3B). The term “exposed” (or “exposing,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

Referring to FIGS. 2 and 3A, each of the first and second source/drain patterns 150A and 150B employed in this embodiment may include a first epitaxial layer 151 and a second epitaxial layer 152 disposed on the first epitaxial layer 151. In this embodiment, the first epitaxial layer 151 may directly contact the side surfaces of the plurality of semiconductor patterns 130. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items. In this embodiment, the first epitaxial layer 151 and the second epitaxial layer 152 may include different materials. For example, in the case of a P-type MOSFET, the first and second epitaxial layers 151 and 152 include SiGe with different Ge components (for example, the second epitaxial layer 152 contains a higher Ge content). Alternatively, the first and second epitaxial layers 151 and 152 may include Si and SiGe, respectively. In some embodiments, the first epitaxial layer 151 and the second epitaxial layer 152 may include different types of impurities or the same impurities at different concentrations. In the case of an N-type MOSFET, the first and second epitaxial layers 151 and 152 may both contain Si, and the first epitaxial layer 151 and the second epitaxial layer 152 may contain different types of impurities or the same impurities at different concentrations.

As illustrated in FIGS. 2 and 3B, the semiconductor device 100 according to this embodiment may further include a first interlayer insulating layer 161 disposed on the device isolation layer 110 to cover the first and second source/drain patterns 150A and 150B, and a second interlayer insulating layer 162 covering the gate structure GS on the first interlayer insulating layer 161. The term “cover” (or “covers,” or like terms), as may be used herein, is intended to broadly refer to an element, structure or layer that is on or over another element, structure or layer, either directly or with one or more other intervening elements, structures or layers therebetween. For example, the first and second interlayer insulating layers 161 and 162 may include Spin-on Hardmask (SOH), Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable chemical vapor deposition (FCVD) oxide, or combinations thereof. The first and second interlayer insulating layers 161 and 162 may be formed, for example, using chemical vapor deposition, flowable CVD process, or spin coating process.

An insulating intermediate liner layer 210 may be disposed in areas between the plurality of insulating isolation patterns 230 on the lower surface of the semiconductor layer 101′. The insulating intermediate liner layer 210 may include an insulating material. For example, the insulating intermediate liner layer 210 may include silicon nitride, silicon oxynitride, aluminum nitride, or aluminum oxynitride.

Referring to FIGS. 2 and 4, the plurality of insulating isolation patterns 230 are spaced apart from each other in the first direction (for example, an X-direction), and may extend in the second direction, (for example, in the Y-direction) intersecting the first direction (for example, X-direction). In this embodiment, each of the insulating isolation patterns 230 may have a portion extending from the lower surface of the semiconductor layer 101′ to the inside. The extended portion of the plurality of insulating isolation patterns 230 may be separated from the plurality of gate structures GS by a portion of the semiconductor layer 101′.

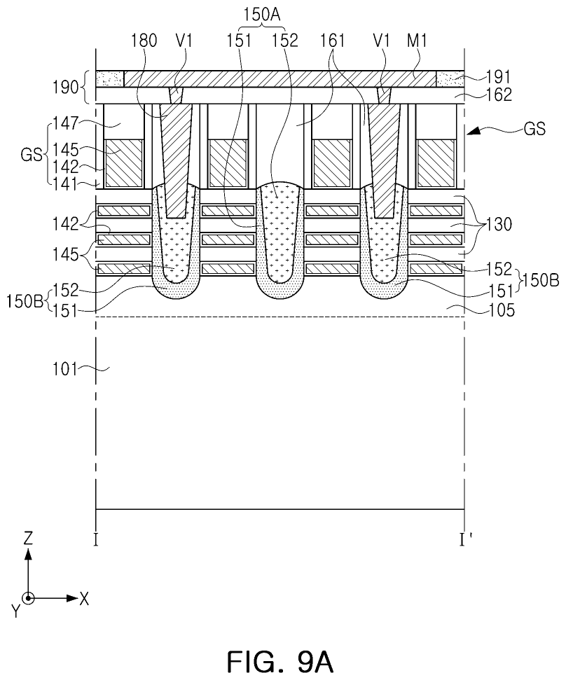

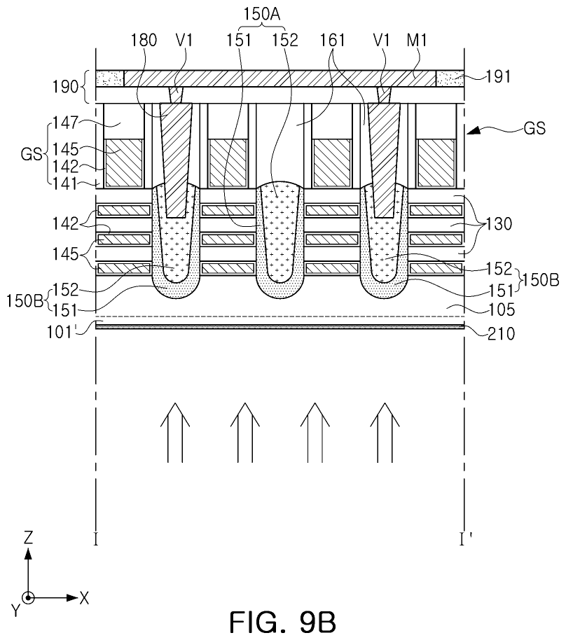

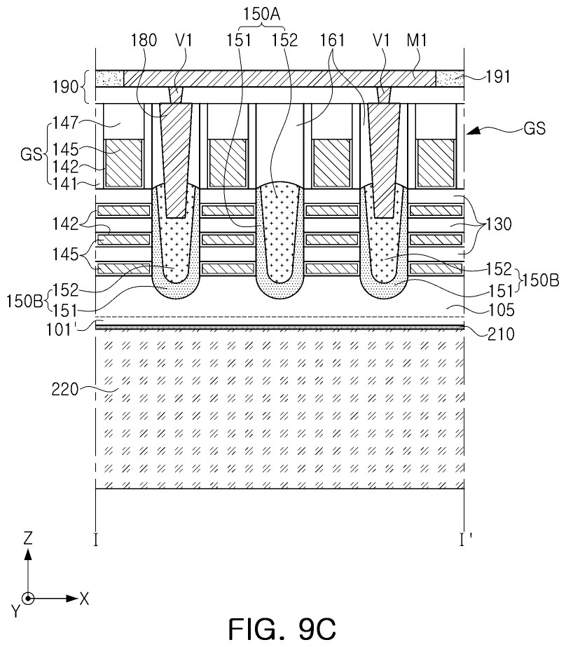

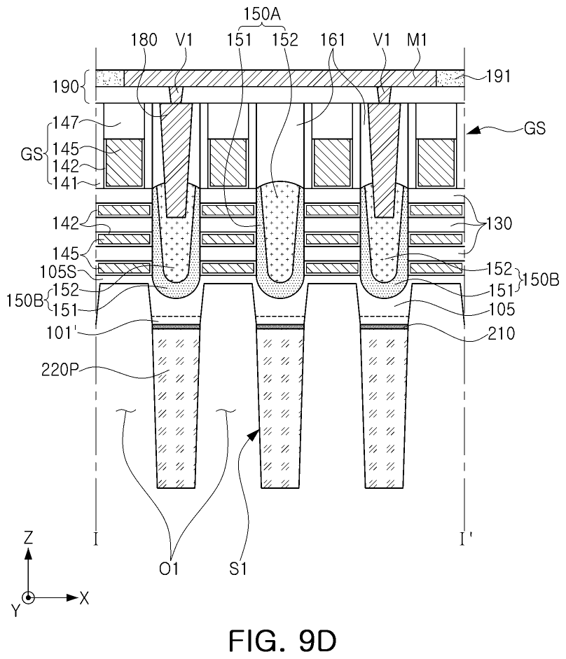

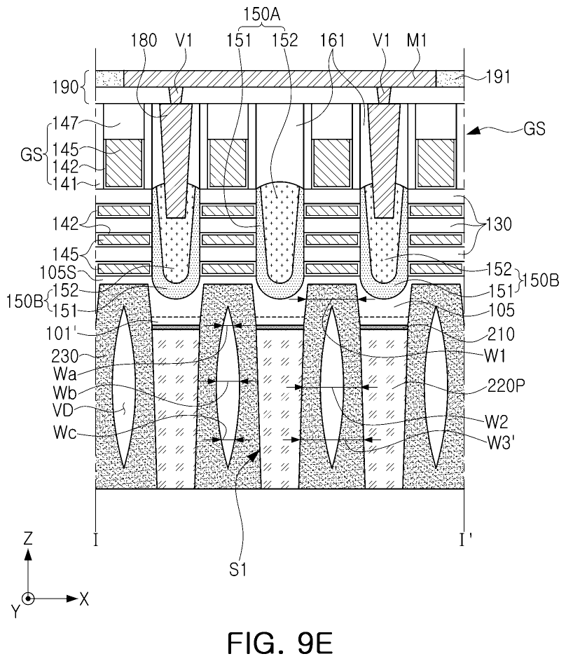

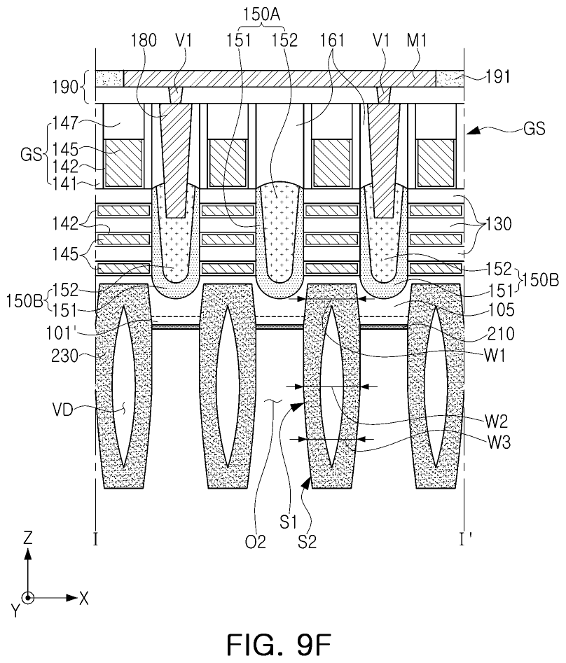

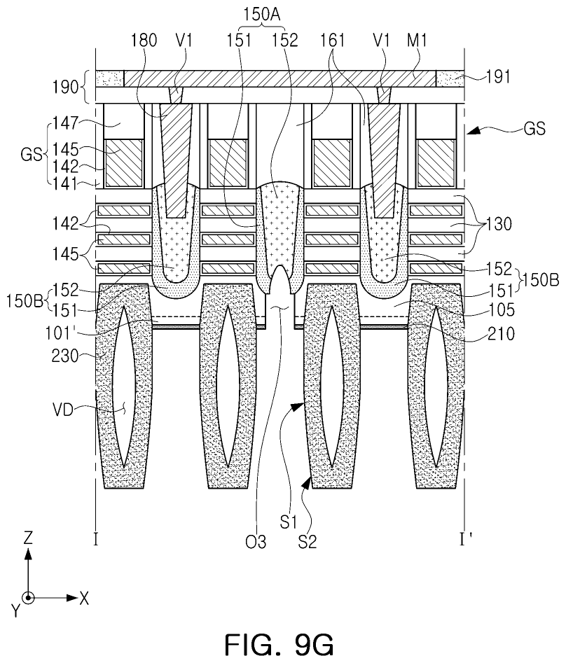

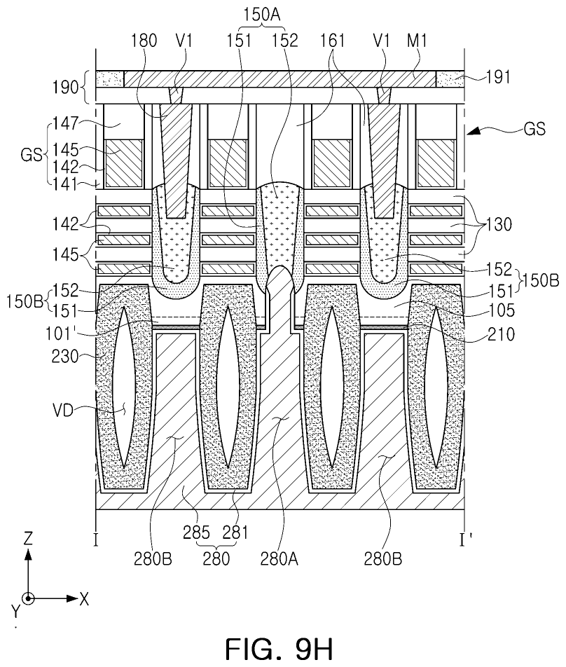

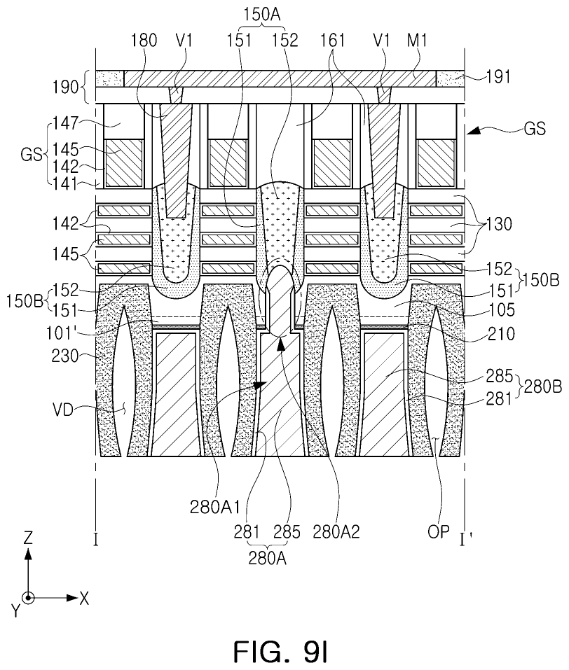

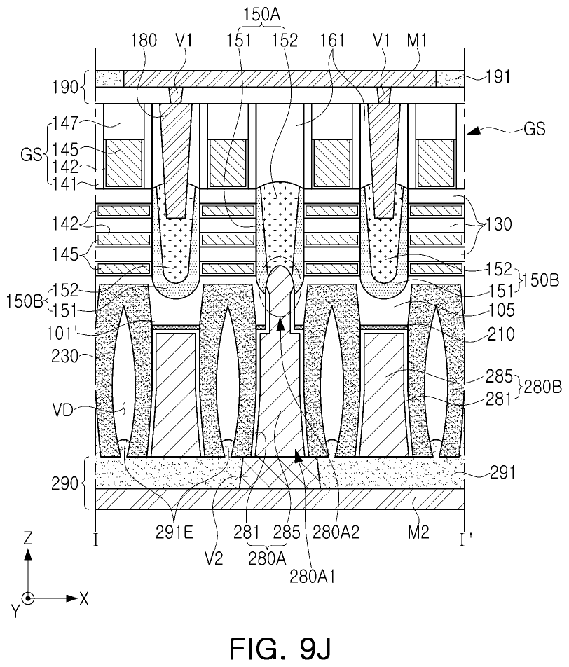

In this embodiment, a portion of the semiconductor layer 101′ (for example, the remaining active pattern 105 in FIG. 3A) may be provided as a margin area to protect the gate structure during an etching process to form the plurality of insulating isolation patterns 230 (see FIG. 9D).

The semiconductor device 100 according to this embodiment may include an upper contact structure 180 extending in a vertical direction (for example, Z-direction) between the gate structures, and lower contact structures 280A and 280B extending in the vertical direction (for example, Z-direction) between the plurality of insulating isolation patterns 230, which are base structures.

In this embodiment, the upper contact structure 180 may penetrate the first interlayer insulating layer 161 and be connected to the first source/drain pattern 150A. The upper contact structure 180 may extend from the upper surface of the second source/drain pattern 150B into the second source/drain pattern 150B.

The lower contact structures 280A and 280B employed in this embodiment may include an active contact structure 280A that participates in the operation of the transistor and a dummy contact structure 280B that does not participate in the operation of the transistor.

As illustrated in FIG. 2, the active contact structure 280A is located below the second source/drain pattern 150A and is configured to be connected to the first source/drain pattern 150A. The dummy contact structure 280B is located below the second source/drain pattern 150B, but may be configured to be electrically separated from the second source/drain pattern 150B. As described above, the second source/drain pattern 150B may be connected by the upper contact structure 180.

In this embodiment, active contact structure 280A may include a body portion (280A1) corresponding to the dummy contact structure 280B, and a contact portion 280A2 extending from the body portion 280A1 and connected to the first source/drain pattern 150A through the semiconductor layer 101′ and the insulating intermediate liner layer 210. As illustrated in FIGS. 2 and 3A, the contact portion 280A2 of the active contact structure 280A may extend from the lower surface of the second source/drain pattern 180A to contact the second epitaxial layer 150b. Meanwhile, the dummy contact structure 280B may be electrically separated from the semiconductor layer 101′ and the second source/drain pattern 150B by the insulating intermediate liner layer 210.

The insulating isolation patterns 230 employed in this embodiment may include voids VD. The void VD extends in the vertical direction (for example, Z-direction) inside each of the insulating isolation patterns 230 (see FIG. 2), and may have a structure in which each insulating isolation pattern extends in an extended second direction (for example, Y-direction) (See FIGS. 3A and 4). These voids VD may be filled by low dielectric materials (for example, air).

Accordingly, the parasitic capacitance generated between other contact structures (for example, the active contact structure 280A and the dummy contact structure 280B) adjacent to each other with the insulating isolation pattern 230 in between may be reduced. As a result, reliability problems such as RC delay of the semiconductor device 100 may be improved.

Referring to FIG. 2, in a cross section in a first direction (for example, X-direction), each of the plurality of insulating isolation patterns 230 may have a middle width W2 that is larger than upper and lower widths W1 and W3, respectively. For example, each cross section of the plurality of insulating isolation patterns 230 may have a substantially hexagonal shape. Similarly, in a cross section in the first direction (for example, X-direction), the void VD may have a middle width Wb that is larger than top and bottom widths Wa and Wc, respectively.

As previously described, the body portion 280A1 of the active contact structure 280A has a structure corresponding to the dummy contact structure 280B. As illustrated in FIG. 4, the body portion 280A1 of the active contact structure 280A and the dummy contact structure 280B are spaced apart from each other in a first direction (for example, X-direction), and may be self-aligned by insulating isolation patterns 230 extending in a second direction (for example, Y-direction) and insulating base patterns 210P located between the insulating isolation patterns 230.

In detail, the width of each of the body portion 280A1 and the dummy contact structure 280B of the active contact structure 280A in the first direction (for example, X-direction) may be defined by the spacing between the plurality of insulating isolation patterns 230. Therefore, in a cross section in the first direction (for example, X-direction) (see FIG. 2), the body portion 280A1 of the active contact structure 280A and the dummy contact structure 280B may each have a middle width that is smaller than the upper and lower widths. Meanwhile, the width of each of the body portion 280A1 and the dummy contact structure 280B of the active contact structure 280A in the second direction (for example, Y-direction) may be defined by the spacing of the insulating base patterns 220P located between the plurality of insulating isolation patterns 230 (see FIG. 4).

The insulating isolation patterns 230 may include a material different from the insulating base pattern 220P. For example, the insulating isolation patterns 230 may include silicon nitride, and the insulating base patterns 220P may include silicon oxide. In some embodiments, the insulating base pattern 220P may include SOH, FOX, TOSZ, USG, BSG, PSG, BPSG, PETEOS, FSG, HDP oxide, PEOX, FCVD oxide, or combinations thereof.

Each of the upper and lower contact structures 180, 280A, and 280B may include a contact plug and a barrier layer surrounding the contact plug. For example, the contact plug may include Cu, Co, Mo, Ru, W, or an alloy thereof. For example, the barrier layer may include Ta, TaN, Mn, MnN, WN, Ti, TiN, or combinations thereof. In this embodiment, the active contact structures 280A may include an insulating liner 282 for electrical insulation from the semiconductor layer 101′. The insulating liner 282 may be formed to surround the surface of a contact plug 285 except for the contact area of the contact plug 285 of the active contact structures 280A. The dummy contact structures 280B may include a contact plug 285 and an insulating liner 282 surrounding the lower and side surfaces of the contact plug 285.

The semiconductor device 100 according to this embodiment has a double-sided interconnection structure including a first interconnection structure 190 and a second interconnection structure 290. The first interconnection structure 190 is provided on the upper surface of the semiconductor device 100, and the second interconnection structure 290 is provided on the lower surface of the semiconductor device 100.

The first interconnection structure 190 may include a first interconnection insulating layer 191 and a first interconnection line M1 disposed in the first interconnection insulating layer 191. The first interconnection line M1 may be electrically connected to the upper contact structure 180 through a first via V1 penetrating (i.e., extending in) the second interlayer insulating layer 162.

Similarly, the second interconnection structure 290 may include second interconnection insulating layers 291 and 292 and a second interconnection line M2 disposed on the second interconnection insulating layers 291 and 292. In this embodiment, while the second interconnection line M2 is electrically insulated from the dummy contact structure 280B by the second interconnection insulating layer 291, the second interconnection line M2 may be electrically connected to the active contact structure 280A through a second via V2 penetrating the second interconnection insulating layer 291.

In this structure, while power for device operation may be supplied to the first source/drain pattern 150A through the second interconnection line M2 and the active contact structure 280A, the dummy contact structure 280B may prevent power from being applied to the dummy contact structure 280B by the second interconnection insulating layer 291 located between the second interconnection line M2 and the insulating isolation patterns 230. Accordingly, the generation of unwanted parasitic capacitance caused by the dummy contact structure 280B may be effectively suppressed.

For example, the first and second interconnection insulating layers 191 and 291 may include a low dielectric material such as silicon oxide, silicon oxynitride, SiOC, or SiCOH. For example, the first and second interconnection lines M1 and M2 may include copper or a copper-containing alloy.

In this embodiment, the void VD of each of the plurality of insulating isolation patterns 230 may be open toward the second interconnection insulating layer 291. The interconnection insulating layer 291 may have a portion 291E extending into the void VD. In this manner, some areas of the void VD may be partially filled with the low dielectric material of the second interconnection insulating layer 291.

The semiconductor device according to this embodiment may be implemented by changing various structures. In some embodiments (FIGS. 5 to 8), the voids VD′ and VD″ in the insulating isolation pattern 230 may have different structures. In some embodiments (FIGS. 5, 7, and 8), the degree of removal of the semiconductor substrate may be different from the previous embodiment, and the shape of the lower contact structure may be changed accordingly.

FIG. 5 is a schematic side cross-sectional view illustrating a semiconductor device according to an example embodiment.

Referring to FIG. 5, the semiconductor device 100A according to this embodiment may be understood as similar to the semiconductor device 100 illustrated in FIGS. 1 to 4, except that the active pattern 105 remains on the semiconductor substrate, and the insulating isolation patterns 230A extend to the lower surface of the gate structures GS and the void VD′ in the insulating isolation patterns 230A is closed (i.e., the void VD′ is entirely surrounded by the insulating isolation patterns 230A). Additionally, unless otherwise stated, the components of this embodiment may be understood with reference to descriptions of the same or similar components of the semiconductor device 100 illustrated in FIGS. 1 to 4.

Unlike the previous embodiment, the base structure employed in this embodiment may include active patterns 105 without a semiconductor layer portion, in addition to the insulating isolation patterns 230 and the insulating base patterns 220P therebetween (see FIG. 4). Additionally, the active patterns 105 may be a plurality of patterns separated by insulating isolation patterns 230A in the first direction (for example, X-direction).

In this manner, since the active patterns 105 related to each of the first and second source/drain patterns 150A and 150B are completely separated from each other by the insulating isolation patterns 230A along the first direction (for example, X-direction), the active contact structure 280A may be formed without an insulating liner (see “281” in FIG. 2).

In this embodiment, the active contact structure 280A may include a contact plug 285 and a conductive barrier 282 surrounding the upper and side surfaces thereof. Similarly, the dummy contact structure 280B may include a contact plug 285 and a conductive barrier 282 surrounding the upper and side surfaces thereof.

As described above, the insulating isolation patterns 230A may extend to the lower surface of the gate structures GS to separate the active patterns 105. The insulating isolation patterns 230A may be formed to directly contact the gate structure GS (for example, gate insulating layer 142) without remaining active patterns (see 105 in FIG. 3A). This structure may be implemented by changing the etching depth in the process of forming the first opening pattern for the insulating isolation pattern 230A during the semiconductor manufacturing process (see FIG. 9D).

In this embodiment, the void VD′ of each of the plurality of insulating isolation patterns 230A may have a structure closed toward the second interconnection insulating layer 291. This process may be implemented by changing the forming process of the insulating isolation pattern 230A (see FIG. 9E) and/or the polishing process for forming the lower contact structure (see FIG. 9I) during the semiconductor manufacturing process.

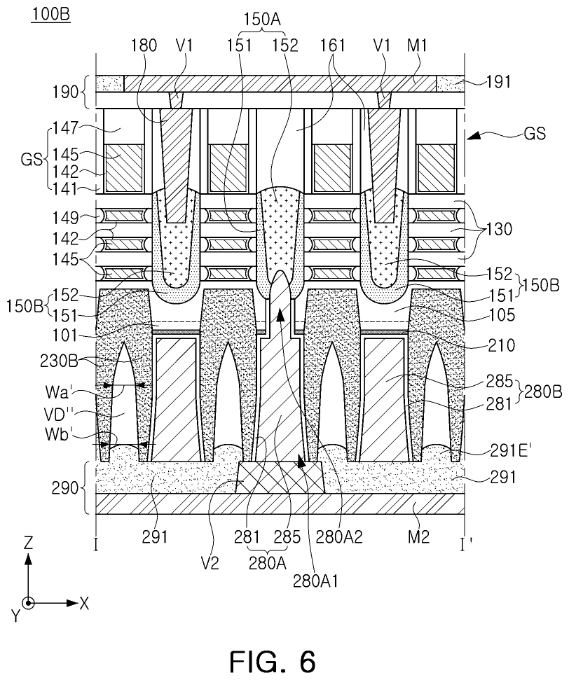

FIG. 6 is a schematic side cross-sectional view illustrating a semiconductor device according to an example embodiment.

Referring to FIG. 6, the semiconductor device 100B according to this embodiment may be understood as similar to the semiconductor device 100 illustrated in FIGS. 1 to 4, except that the method of forming the voids VD″ in the insulating isolation patterns 230B is different and the internal spacers 149 are disposed on both sides of the plurality of semiconductor patterns 130. Additionally, unless otherwise stated, the components of this embodiment may be understood with reference to descriptions of the same or similar components of the semiconductor device 100 illustrated in FIGS. 1 to 4.

In this embodiment, the voids VD″ of the insulating isolation patterns 230B may be obtained through an additional etching process after forming the insulating isolation patterns 230B. For example, if the void is small or not formed in the initial insulating isolation pattern formation process (see FIG. 9E), the void is removed by etching the central area of the insulating isolation patterns 230B in the subsequent process (for example, see FIG. 9I). VD″ may be formed. In this case, the void VD″ employed in this embodiment does not extend long in the second direction (for example, Y-direction), and may be formed to have a length corresponding to the length of the lower contact structures 280 in the second direction (for example, Y-direction) (see FIG. 4).

When forming a void by an additional etching process after forming the insulating isolation pattern 230B, the void VD″ may have a lower width Wb′ that is greater than an upper width (Wa′) in a cross section in the first direction (for example, X-direction). Additionally, the size and depth of the portion 291E′ extending into the void VD″ of the second interconnection insulating layer 291 may be changed.

The gate structure GS according to this embodiment may include internal spacers 149. The internal spacers 149 may be disposed on both sides of portions of the gate electrode 145 (i.e., on opposing ends of the gate electrode 145 in the first direction (X-direction)) between the plurality of semiconductor patterns 130. In some embodiments, the gate electrode portions may be surrounded by portions of the gate insulating layer 142 in the first direction (for example, X-direction). The gate electrode portions and the gate insulating portions may be spaced apart from the first and second source/drain patterns 150A and 150B by the internal spacers 149. The internal spacers 149 may have convex sides toward the gate electrode portions, but are not limited thereto. For example, internal spacers 149 may include low dielectric materials such as oxides, nitrides, and oxynitrides.

FIG. 7 is a schematic side cross-sectional view illustrating a semiconductor device according to an example embodiment.

Referring to FIG. 7, the semiconductor device 100C according to this embodiment may be understood as similar to the semiconductor device 100 illustrated in FIGS. 1 to 4, except that the semiconductor substrate is completely removed, the insulating intermediate liner layer 210 is formed along the lower surfaces of the gate structures GS and the first and second source/drain patterns 150A and 150B, the method of forming the voids VD″ in the insulating isolation patterns 230B is different and the internal spacers 149 are disposed on both sides of the plurality of semiconductor patterns 130. Additionally, unless otherwise stated, the components of this embodiment may be understood with reference to descriptions of the same or similar components of the semiconductor device 100 illustrated in FIGS. 1 to 4.

In this embodiment, since there is no semiconductor substrate portion, each of the first and second source/drain patterns 150A and 150B may be separated from each other along the first direction (for example, X-direction). Accordingly, the active contact structure 280A′ may include a contact plug 285 and a conductive barrier 282 surrounding the upper and side surfaces thereof without an insulating liner (see “281” in FIG. 2). Similarly, the dummy contact structure 280B′ may include a contact plug 285 and a conductive barrier 282 surrounding the upper and side surfaces thereof.

As in this embodiment, all of the semiconductor substrate portion (semiconductor layer 101′ and active pattern 105, as shown in FIG. 2) may be removed. In this case, the insulating intermediate liner layer 210 may be formed along the lower surfaces of the gate structures GS and the first and second source/drain patterns 150A and 150B. The dummy contact structure 280B′ is electrically insulated from the second source/drain pattern 150B by the insulating intermediate liner layer 210, and the active contact structure 280A′ may be connected to the first source/drain pattern by a contact portion 280A2 penetrating (i.e., extending into or through) the insulating intermediate liner layer 210.

The voids VD″ in the insulating isolation patterns 230B may be obtained through an additional etching process after forming the insulating isolation patterns 230B, similar to the example embodiment of FIG. 6. The size and depth of the portion 291E′ extending into the void VD″ of the second interconnection insulating layer 291 may be changed. Additionally, the semiconductor device 100C according to this embodiment may have internal spacers 149 disposed on both sides of the plurality of semiconductor patterns 130, similar to the example embodiment of FIG. 6.

FIG. 8 is a schematic side cross-sectional view illustrating a semiconductor device according to an example embodiment.

Referring to FIG. 8, the semiconductor device 100D according to this embodiment may be understood as similar to the semiconductor device 100 illustrated in FIGS. 1 to 4, except that the semiconductor substrate is completely removed, the sacrificial patterns 160 are located below some of the source/drain patterns 150B, the insulating intermediate liner layer 210 is formed along the lower surfaces of the gate structures GS and the sacrificial patterns 160, the method of forming the voids VD″ in the insulating isolation patterns 230B is different and the internal spacers 149 are disposed on both sides of the plurality of semiconductor patterns 130. Additionally, unless otherwise stated, the components of this embodiment may be understood with reference to descriptions of the same or similar components of the semiconductor device 100 illustrated in FIGS. 1 to 4.

Similar to the previous embodiment (FIG. 7), all of the semiconductor substrate portion (semiconductor layer 101′ and active pattern 105, as shown in FIG. 2) may be removed. In this embodiment, the insulating intermediate liner layer 210 is formed along the lower surfaces of the gate structures GS and the first and second source/drain patterns 150A and 150B, and sacrificial patterns 160 may be located below the second source/drain patterns 150B. The sacrificial patterns 160 may be formed after a recess process for forming the first and second source/drain patterns 150A and 150B, and before forming the first and second source/drain patterns 150A and 150B. After selectively removing the insulating intermediate liner layer 210 (see FIG. 9G), only the sacrificial pattern below the first source/drain pattern 150A among the sacrificial patterns 160 is removed, and an active contact structure 280A″ connected to the first source/drain pattern 150A may be formed through the space removed from the sacrificial pattern. As a result, the sacrificial pattern 160 below the second source/drain pattern 150B remains, and the remaining sacrificial pattern 160 may be separated from the dummy contact structure 280B″ by the insulating intermediate liner layer 210. The active contact structure 280A″ may have a contact portion 280A2 having a structure corresponding to the removed sacrificial pattern.

The active contact structure 280A″ may include a contact plug 285 and a conductive barrier 282 surrounding the upper and side surfaces thereof, similar to the example embodiment illustrated in FIG. 7. Similarly, the dummy contact structure 280B″ may include a contact plug 285 and a conductive barrier 282 surrounding the upper and side surfaces thereof.

The void VD″ in the insulating isolation patterns 230B may be obtained through an additional etching process after forming the insulating isolation pattern 230B, similar to the example embodiments of FIGS. 6 and 7. The size and depth of the portion 291E′ extending into the void VD″ of the second interconnection insulating layer 291 may be changed. Additionally, the semiconductor device 100D according to this embodiment may have internal spacers 149 disposed on both sides of the plurality of semiconductor patterns 130, similar to the example embodiments of FIGS. 6 and 7.

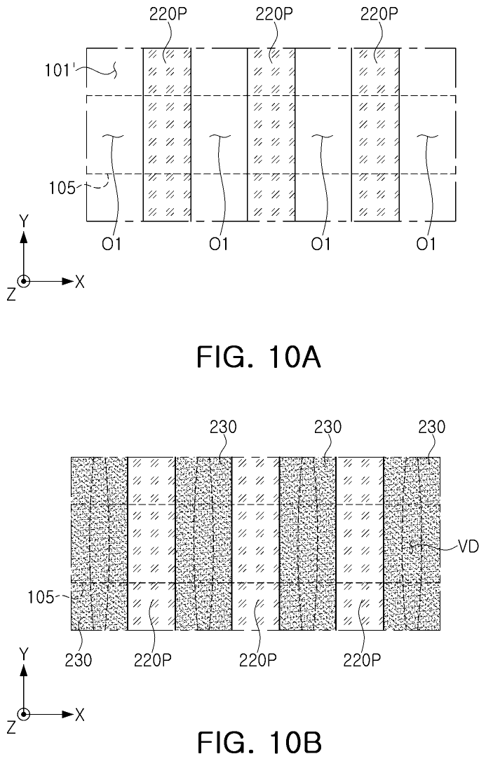

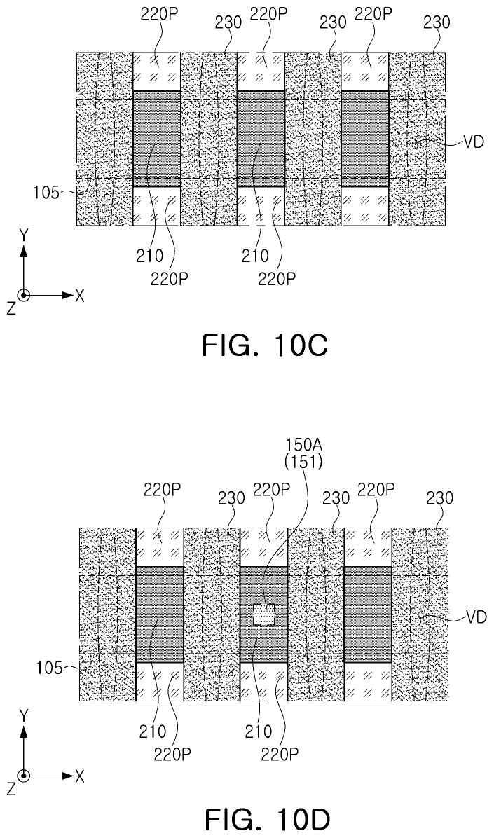

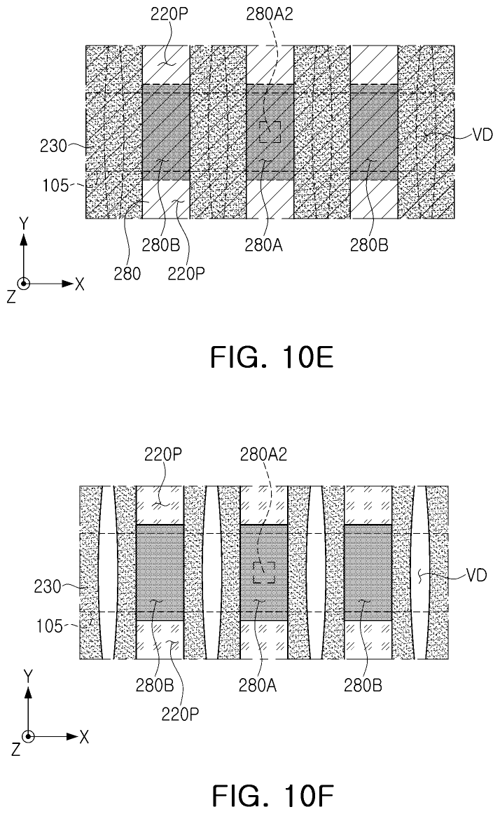

FIGS. 9A to 9J are schematic cross-sectional views of intermediate processes in a method of manufacturing a semiconductor device according to an example embodiment, and FIGS. 10A to 10F are schematic lower plan views of FIGS. 9D to 9I, respectively. The manufacturing process described in FIGS. 9A to 9J and 10A to 10F may be understood as a process for manufacturing the semiconductor device 100 illustrated in FIGS. 1 to 4.

Referring to FIG. 9A, on the semiconductor substrate 101, gate all around (GAA) type transistor elements including a plurality of channel structures, a plurality of gate structures GS, and first and second source/drain patterns 150A and 150B may be formed.

The semiconductor substrate 101 may include a semiconductor material, for example, a group IV semiconductor, a group III-V compound semiconductor, or a group II-VI compound semiconductor. For example, the group IV semiconductor may include silicon (Si), germanium (Ge), or silicon germanium (SiGe). The substrate 101 may include a bulk wafer, an epitaxial layer, or a silicon on insulator (SOI) layer.

The plurality of channel structures may include a plurality of semiconductor patterns 130 stacked and spaced apart from each other in a vertical direction (i.e., Z-direction) on the active pattern 105 and extending in the first direction (for example, X-direction). The plurality of gate structures GS may each cross the plurality of channel structures in the second direction (for example, Y-direction) and may be formed to surround the plurality of semiconductor patterns 130. The first and second source/drain patterns 150A and 150B are disposed in a recess area extending to a portion of the active pattern 105 between the plurality of channel structures. The first and second source/drain patterns 150A and 150B may be respectively connected to both sides of the plurality of semiconductor patterns 130 in the first direction (for example, X-direction). Additionally, a first interlayer insulating layer 161 is formed between the plurality of gate structures GS to cover the first and second source/drain patterns 150A and 150B, and an upper contact structure 180 electrically connected to the first source/drain pattern 150A may be formed through the first interlayer insulating layer 161. Furthermore, a second interlayer insulating layer 162 is formed on the first interlayer insulating layer 161 to cover the plurality of gate structures GS, and a first interconnection structure 190 electrically connected to the upper contact structure 180 may be formed.

Next, referring to FIG. 9B, the semiconductor substrate 101 may be partially removed to leave a semiconductor layer 101′ of a certain thickness in the vertical direction (i.e., Z-direction), and an insulating intermediate liner layer 210 may be formed on the lower surface of the semiconductor layer 101′.

A partial removal process of the semiconductor substrate 101 (see FIG. 9A) may be performed by a polishing process and/or an etching process. In this embodiment, the semiconductor layer 101′ of a predetermined thickness remains along with the active pattern 105, but after the semiconductor layer is completely removed, only the active pattern may remain (see FIG. 5) or the active pattern may be almost completely removed (see FIG. 7). Next, the insulating intermediate liner layer 210 may be formed on the lower surface of the semiconductor layer 101 using a deposition process such as chemical vapor deposition (CVD). For example, the insulating intermediate liner layer 210 may be silicon nitride, silicon oxynitride, aluminum nitride, aluminum oxide, or aluminum oxynitride.

Next, referring to FIG. 9C, an insulating base layer 220 may be formed on the insulating intermediate liner layer 210 (e.g., on a lower surface of the intermediate liner layer 210).

The insulating base layer 220 may include, for example, SOH, FOX, TOSZ, USG, BSG, PSG, BPSG, PETEOS, FSG, HDP oxide, PEOX, FCVD oxide, or combinations thereof. For example, the insulating base layer 220 may be formed using chemical vapor deposition, flowable CVD process, or spin coating process.

Next, referring to FIGS. 9D and 10A, the insulating base layer 220 (see FIG. 9C) and the insulating intermediate liner layer 210 may be partially removed to form a plurality of first opening patterns O1.

The plurality of first opening patterns O1 may be formed in corresponding areas under each of the plurality of gate structures GS in the insulating base layer 220 (see FIG. 9C) using a selective etching process.

The plurality of first opening patterns O1 may be formed to have a depth in the vertical direction (i.e., Z-direction) that extends beyond the insulating intermediate liner layer 210 to a partial region of the semiconductor layer 101′. Due to differences in etch rates, the inner sidewall of the semiconductor layer 101′ and the inner sidewall of the insulating base layer 220 may have different profiles (for example, inclination angles). For example, an inner sidewall S1 of the insulating base layer 220 may have an inclination angle closer to vertical than the inclination angle of the inner sidewall of the semiconductor layer 101′.

In this embodiment, a portion of the semiconductor layer may remain on the bottom surface of the plurality of first opening patterns O1. The remaining semiconductor layer portion may be understood as a margin area to prevent damage to the gate structures GS.

Referring to FIG. 10A, the plurality of first opening patterns O1 are spaced apart from each other in a first direction (for example, X-direction), and each may have a line shape extending in a second direction (for example, Y-direction). The remaining insulating base patterns 220P may be alternately arranged with the plurality of first opening patterns O1 in the first direction (for example, X-direction). The plurality of first opening patterns O1 may be provided as spaces for forming the plurality of insulating isolation patterns 230 (see FIG. 9E).

Next, referring to FIGS. 9E and 10B, insulating isolation patterns 230 may be formed in each of the plurality of first opening patterns O1.

In this embodiment, a deposition process may be performed to form insulating isolation patterns 230 in the plurality of first opening patterns O1. During the deposition of the insulating material, the entrance of the first opening pattern O1 may be closed, thereby forming a void VD in the form of a seam inside the insulating isolation patterns 230. The size and shape of the void VD may change depending on deposition process conditions and the shape (particularly, aspect ratio) of the first opening patterns O1 (see FIG. 9D). In this embodiment, voids VD may be introduced into a low-dielectric structure to reduce parasitic capacitance of adjacent contact structures. In some embodiments, the void VD may be very thin and small, or the insulating isolation patterns 230 may have a structure that is almost completely filled without the void VD. In this case, the small void may be expanded or a desired void may be formed through a subsequent etching process (see FIGS. 6 to 8). For example, the insulating isolation patterns 230 may include silicon nitride or silicon oxynitride.

The plurality of insulating isolation patterns 230 formed in this process may be defined by the shape of the first opening pattern O1. For example, in a cross section in a first direction (for example, X-direction), each of the plurality of insulating isolation patterns 230 may have a middle width W2 that is larger than the upper width W1 and larger than the lower widths W3′. Meanwhile, in the cross section in the first direction (for example, X-direction), the void VD may have a middle width Wb that is larger than the top and bottom widths Wa and Wc.

In the process of forming the plurality of insulating isolation patterns 230, the plurality of insulating isolation patterns 230 are formed to cover the insulating base patterns 220P, and additionally, through the polishing process, the lower surface of the insulating base pattern 220P is exposed, as illustrated in FIG. 9E, and the lower surfaces of the insulating isolation patterns 230 may have a substantially flat surface.

Referring to FIG. 10B, the insulating isolation patterns 230 are spaced apart from each other in a first direction (for example, X-direction) and may each extend in a second direction (for example, Y-direction). Additionally, the insulating isolation patterns 230 may be alternately arranged in the second direction.

Next, referring to FIGS. 9F and 10C, the insulating base pattern 220P (see FIG. 9E) may be at least partially removed to prepare second opening patterns O2 for the lower contact structure.

The second opening patterns O2 may be formed by selectively removing portions of the insulating base pattern 220P located below each of the first and second source/drain patterns 150A and 150B. In this removal process, the insulating intermediate liner layer 210 may be used as an etch stop layer. The insulating intermediate liner layer 210 may be exposed on the bottom surfaces of the second opening patterns O2. In the process of forming the second opening patterns O2, the lower regions of the insulating isolation patterns 230 may be additionally etched. The lower region of the insulating isolation patterns 230 defining sidewalls of the second opening patterns O2 may have an additional inclined sidewall S2. The lower region of the insulating isolation patterns 230 may have a sidewall S2 that is inclined more than the sidewall S1 of the middle region. As a result, the bottom width W3 of the insulating isolation patterns 230 in the first direction (for example, X-direction) may be smaller than the middle width W2.

The width of each of the second opening patterns O2 in the first direction (for example, X-direction) is defined by the spacing between the plurality of insulating isolation patterns 230, and the width of each of the second opening patterns O2 in the second direction (for example, Y-direction) may be defined by the spacing between the insulating base patterns 220P located between the plurality of insulating isolation patterns 230. (see FIG. 10C).

Next, referring to FIGS. 9G and 10D, a portion of the insulating intermediate liner layer 210 exposed to some of the second opening patterns O2 is selectively removed, and the semiconductor layers 101 and 105 may be etched through the removed areas to form a third opening O3.

This selective removal process may be applied to the second opening pattern O2 located below the first source/drain patterns 150A. By removing a portion of the insulating intermediate liner layer 210 exposed to the second opening pattern O2 and removing the semiconductor layers 101 and 105 through the removed area, the third opening O3 connected to the first source/drain pattern 150A may be formed. The second opening pattern O2 with the third opening O3 is provided as a space to form an active contact structure 280A (see FIG. 9H) to be connected to the first source/drain pattern 150A, and the third opening O3 may be provided as a space to form the contact portion 280A2 (see FIG. 9I) of the active contact structure 280A. Additionally, the remaining second opening patterns O2 may be provided as areas to form dummy contact structures 280B (see FIG. 9H) below the second source/drain patterns 150B.

Next, referring to FIGS. 9H and 10E, the lower contact structure 280 may be formed by filling the second opening patterns O2 with a conductive material 285 (or a contact plug). The term “filling” (or “fill,” or like terms) is intended to refer to either completely filling a defined space (e.g., the second opening patterns O2) or partially filling the defined space; that is, the defined space need not be entirely filled but may, for example, be partially filled or have voids or other spaces throughout.

Before depositing the conductive material 285, an insulating liner 281 may be conformally formed along the surface exposed by the second opening pattern O2 and the third opening O3. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. Subsequently, the portion located in the third opening O3 of the insulating liner 281 may be selectively removed to expose the first source/drain pattern 150A.

Next, the conductive material 285 connected to the exposed area of the first source/drain pattern 150A may be formed on the insulating liner 281 through the third opening O3. The lower contact structure 280 may include an active contact structure 280A connected to the first source/drain pattern 150A and a dummy contact structure 280B located below the second source/drain pattern 150B. As illustrated in FIG. 9H, the insulating liner 281 and the conductive material 285 may also be formed on the lower surfaces of the insulating isolation patterns 230. As illustrated in FIGS. 5, 7, and 8, when there is no semiconductor layer, the insulating liner 281 may be omitted when forming the lower contact structure 280.

Next, referring to FIGS. 9I and 10F, a polishing process may be performed to remove some of the conductive material 285 and some of the insulating liner 281 to expose the lower surfaces of the insulating isolation patterns 230.

Through this polishing process, the lower contact structure 280 may be separated into an active contact structure 280A and a dummy contact structure 280B by insulating isolation patterns 230. Additionally, in this embodiment, the void VD within the insulating isolation patterns 230 may be opened through this polishing process.

Next, referring to FIG. 9J, the second interconnection structure 290 may be formed on the insulating isolation patterns 230 and the insulating base patterns 220P and on the active contact structure 280A and the dummy contact structure 280B. The second interconnection structure 290 may include a second interconnection insulating layer 291, a second via V2, and a second interconnection line M2.

The second interconnection insulating layer 291 may be formed on the insulating isolation patterns 230 and the insulating base patterns 220P, the active contact structure 280A, and the dummy contact structure 280B. The second interconnection insulating layer 291 may have a portion 291E extending in a partial area of the void of the insulating isolation patterns 230. Subsequently, after forming the additional second interconnection insulating layer 292, the second interconnection line M2 having the second via V2 may be formed using a dual damascene process. In this case, the second interconnection line M2 may be electrically connected to the active contact structure 280A through the second via V2 penetrating the second interconnection insulating layer 291. On the other hand, the second interconnection line M2 is insulated from the dummy contact structure 280B by the second interconnection insulating layer 291 to prevent power from being applied to the dummy contact structure 280B.

As set forth above, according to the above-described embodiments, by forming voids inside insulating isolation patterns and introducing a backside insulating layer to prevent voltage application to a dummy contact structure, parasitic capacitance generated by the backside contact structures (in detail, the dummy contact structure) may be effectively reduced.

While example embodiments have been illustrated and described above, it will be apparent to those skilled in the art that modifications and variations could be made without departing from the scope of the present inventive concept as defined by the appended claims.

What is claimed is:

1. A semiconductor device, comprising:
a plurality of insulating isolation patterns spaced apart from each other in a first direction and each extending in a second direction intersecting the first direction, each of the plurality of insulating isolation patterns including a void;
a plurality of channel structures respectively on the plurality of insulating isolation patterns and each having a plurality of semiconductor patterns stacked and spaced apart from each other in a vertical direction intersecting the first and second directions;
a plurality of gate structures respectively intersecting the plurality of channel structures in the second direction and extending around the plurality of semiconductor patterns;
a first source/drain pattern and a second source/drain pattern between the plurality of channel structures and respectively connected to opposing sides of the plurality of semiconductor patterns in the first direction;
an active contact structure between insulating isolation patterns adjacent to the first source/drain pattern among the plurality of insulating isolation patterns, and electrically connected to the first source/drain pattern;
a dummy contact structure between insulating isolation patterns adjacent to the second source/drain pattern among the plurality of insulating isolation patterns, and electrically isolated from the second source/drain pattern; and
an interconnection line on lower surfaces of the plurality of insulating isolation patterns, electrically connected to the active contact structure, and electrically isolated from the dummy contact structure.

2. The semiconductor device of claim 1, further comprising an interconnection insulating layer between the plurality of insulating isolation patterns and the interconnection line, and
an interconnection via extending in the interconnection insulating layer to electrically connect the interconnection line and the active contact structure.

3. The semiconductor device of claim 2, wherein the void in each of the plurality of insulating isolation patterns is open toward the interconnection insulating layer.

4. The semiconductor device of claim 3, wherein the interconnection insulating layer has a portion extending into the void.

5. The semiconductor device of claim 2, wherein the void is closed toward the interconnection insulating layer.

6. The semiconductor device of claim 1, wherein in a cross section in the first direction, each insulating isolation pattern of the plurality of insulating isolation patterns has a middle portion of a first width, a top portion of a second width, and a bottom portion of a third width, the first width greater than the second width and the third width, the middle portion between the top and bottom portions.

7. The semiconductor device of claim 1, wherein in a cross section in the first direction, the void has a middle width greater than top and bottom widths.

8. The semiconductor device of claim 1, wherein in a cross section in the first direction, a bottom width of the void in each of the plurality of insulating isolation patterns is greater than a top width of the void.

9. The semiconductor device of claim 1, further comprising:
a semiconductor layer on lower surfaces of the plurality of gate structures and on lower surfaces of the first and second source/drain patterns; and
an insulating intermediate liner layer on a lower surface of the semiconductor layer.

10. The semiconductor device of claim 9, wherein the plurality of insulating isolation patterns include extended portions extending through the semiconductor layer and the insulating intermediate liner layer and extending toward the plurality of gate structures.

11. The semiconductor device of claim 10, wherein a portion of the semiconductor layer remains between the extended portions of the plurality of insulating isolation patterns and the plurality of gate structures.

12. The semiconductor device of claim 9, wherein the dummy contact structure is spaced apart from the semiconductor layer by the insulating intermediate liner layer, and
the active contact structure includes a body portion corresponding to the dummy contact structure, and a contact portion extending from the body portion and electrically connected to the first source/drain pattern by extending through the semiconductor layer and the insulating intermediate liner layer.

13. The semiconductor device of claim 12, wherein in a cross section in the first direction, each of the dummy contact structure and the body portion has a middle portion of a first width, a top portion of a second width, and a bottom portion of a third width, the first width smaller than the second width and the third width, the middle portion between the top and bottom portions.

14. The semiconductor device of claim 1, further comprising an insulating intermediate liner layer along lower surfaces of the plurality of gate structures and on lower surfaces of the first and second source/drain patterns.

15. The semiconductor device of claim 14, further comprising a sacrificial pattern between a lower surface of the second source/drain pattern and the insulating intermediate liner layer.

16. The semiconductor device of claim 14, wherein the active contact structure includes a contact portion electrically connected to the first source/drain pattern by extending through the insulating intermediate liner layer, and
the dummy contact structure is electrically isolated from the second source/drain pattern by the insulating intermediate liner layer.

17. A semiconductor device, comprising:
a plurality of insulating isolation patterns spaced apart from each other in a first direction and each extending in a second direction intersecting the first direction, each of the plurality of insulating isolation patterns including a void;
a plurality of channel structures respectively on the plurality of insulating isolation patterns and each having a plurality of semiconductor patterns stacked and spaced apart from each other in a vertical direction intersecting the first and second directions;
a plurality of gate structures respectively intersecting the plurality of channel structures in the second direction and extending around the plurality of semiconductor patterns;
a first source/drain pattern and a second source/drain pattern between the plurality of channel structures and respectively connected to opposing sides of the plurality of semiconductor patterns in the first direction;
an upper contact structure extending in the vertical direction between the plurality of gate structures and electrically connected to the second source/drain pattern;
an active contact structure extending in the vertical direction between insulating isolation patterns adjacent to the first source/drain pattern among the plurality of insulating isolation patterns, and electrically connected to the first source/drain pattern;
a dummy contact structure extending in the vertical direction between insulating isolation patterns adjacent to the second source/drain pattern among the plurality of insulating isolation patterns and electrically isolated from the second source/drain pattern;
an interconnection insulating layer on lower surfaces of the plurality of insulating isolation patterns and having portions extending into the void of each of the plurality of insulating isolation patterns; and
an interconnection line on a lower surface of the interconnection insulating layer and having an interconnection via extending through the interconnection insulating layer and electrically connected to the active contact structure.

18. The semiconductor device of claim 17, further comprising a semiconductor layer on lower surfaces of the plurality of gate structures and on lower surfaces of the first and second source/drain patterns, and an insulating intermediate liner layer on a lower surface of the semiconductor layer, and
wherein the plurality of insulating isolation patterns extend through the semiconductor layer and the insulating intermediate liner layer and extend toward the plurality of gate structures.

19. The semiconductor device of claim 18, wherein the active contact structure comprises:
a body portion between insulating isolation patterns adjacent to the first source/drain pattern of the plurality of insulating isolation patterns and having a structure corresponding to the dummy contact structure; and
a contact portion extending from the body portion, extending in the semiconductor layer and the insulating intermediate liner layer, and electrically connected to the first source/drain pattern.

20. A semiconductor device, comprising:
a base structure having an insulating isolation pattern extending in a first direction, the insulating isolation pattern having a void therein;
a plurality of semiconductor patterns stacked on the insulating isolation pattern and spaced apart from each other in a vertical direction perpendicular to an upper surface of the base structure;
a gate structure extending around the plurality of semiconductor patterns in a second direction crossing the first direction;
a first source/drain pattern and a second source/drain pattern on opposing sides of the gate structure in the first direction and connected to the plurality of semiconductor patterns;
an active contact structure extending in the vertical direction from a lower surface of the base structure, extending through the base structure and electrically connected to the first source/drain pattern;
a dummy contact structure extending in the vertical direction from the lower surface of the base structure and spaced apart from the active contact structure with the insulating isolation pattern therebetween; and
an interconnection line on lower surfaces of the active contact structure, the dummy contact structure, and the insulating isolation pattern, electrically connected to the active contact structure, and electrically isolated from the dummy contact structure.
